(19) United States
(12) Patent Application Publication
(10) Pub. No.: US 2025/0054865 A1
(43) Pub. Date: Feb. 13, 2025

(54) SEMICONDUCTOR INTEGRATED CIRCUIT DEVICE

(71) Applicant: Socionext Inc., Kanagawa (JP)

(72) Inventor: Kazuhiro NAKAMURA, Yokohama-shi (JP)

(21) Appl. No.: 18/927,320

(22) Filed: Oct. 25, 2024

Related U.S. Application Data
(63) Continuation of application No. PCT/JP2022/019350, filed on Apr. 28, 2022.

(51) Int. Cl. H01L 23/528; H01L 23/00

(52) U.S. Cl. CPC H01L 23/5286; H01L 23/5283; H01L 24/05; H01L 2224/05009

(57) ABSTRACT

A semiconductor integrated circuit device includes a plurality of standard cells including a first standard cell, arranged in line in a first direction. A first buried power rail supplying a first power supply voltage is laid in a first impurity region supplied with the first power supply voltage, and extends in the first direction. A second buried power rail supplying a second power supply voltage is laid in a second impurity region supplied with the second power supply voltage, and extends in the first direction. The first standard cell includes a third buried power rail laid in the first impurity region and supplied with the second power supply voltage.

### CROSS-REFERENCE TO RELATED APPLICATIONS

This is a continuation of International Application No. PCT/JP2022/019350 filed on Apr. 28, 2022. The entire disclosure of this application is incorporated by reference herein.

### BACKGROUND

The present disclosure relates to a semiconductor integrated circuit device using buried power rails (BPRs).

For higher integration of a semiconductor integrated circuit, it is proposed to use buried power rails (BPRs) made of metal interconnects laid in a buried interconnect (BI) layer buried in a substrate or a shallow trench isolation (STI), not power supply lines laid in a metal interconnect layer formed above transistors as conventionally done.

WO 2020/110733 discloses a configuration in which buried power rails are used as power supply lines for a capacitive cell using nanowire FETs.

In the configuration of the cited document, only some of the transistors of the capacitive cell function as a capacitor, and therefore, sufficient capacitance cannot be obtained.

An objective of the present disclosure is providing a configuration of a capacitive cell capable of obtaining sufficient capacitance in a semiconductor integrated circuit device having buried power rails.

### SUMMARY

According to one mode of the present disclosure, a semiconductor integrated circuit device includes a plurality of standard cells including a first standard cell, arranged in line in a first direction, wherein the plurality of standard cells include a first impurity region of a first conductivity type formed in a substrate and supplied with a first power supply voltage, a second impurity region of a second conductivity type formed in the substrate and supplied with a second power supply voltage, a first buried power rail laid in the first impurity region, extending in the first direction and supplying the first power supply voltage, and a second buried power rail laid in the second impurity region, extending in the first direction and supplying the second power supply voltage, and the first standard cell includes a third buried power rail laid in the first impurity region and supplied with the second power supply voltage.

According to the above mode, in a plurality of standard cells, the first buried power rail supplying the first power supply voltage is laid in the first impurity region of the first conductivity type supplied with the first power supply voltage, and extends in the X direction. The second buried power rail supplying the second power supply voltage is laid in the second impurity region of the second conductivity type supplied with the second power supply voltage, and extends in the X direction. In the first standard cell, the third buried power rail supplied with the second power supply voltage is laid in the first impurity region. This forms a capacitance between the third buried power rail and the first impurity region, whereby the first standard cell can obtain sufficient capacitance.

According to the present disclosure, sufficient capacitance can be obtained in a semiconductor integrated circuit device having buried power rails.

### BRIEF DESCRIPTION OF THE DRAWINGS

FIG. 1 is a plan view of a standard cell provided in a semiconductor integrated circuit device according to the first embodiment.

FIGS. 2A and 2B are cross-sectional views showing cross-sectional structures of the standard cell of FIG. 1.

FIG. 3 shows a layout example of a plurality of standard cells arranged in line.

FIG. 4 shows a circuit configuration of an inverter cell.

FIGS. 5A and 5B are cross-sectional views showing cross-sectional structures of a standard cell of Alteration 1.

FIGS. 6A and 6B are cross-sectional views showing cross-sectional structures of a standard cell of Alteration 2.

FIGS. 7A and 7B are cross-sectional views showing cross-sectional structures of a standard cell of Alteration 2.

FIG. 8 shows an overall configuration of a semiconductor integrated circuit device according to the second embodiment.

FIGS. 9A and 9B are cross-sectional views showing cross-sectional structures of a standard cell provided in the semiconductor integrated circuit device of the second embodiment.

### DETAILED DESCRIPTION

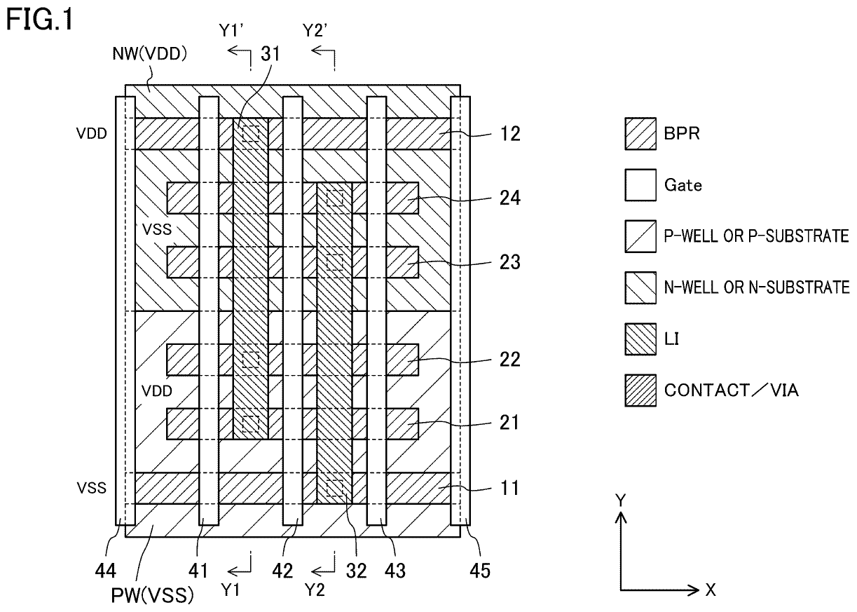

Embodiments of the present disclosure will be described hereinafter with reference to the accompanying drawings. Note that, in the following description, in the plan views such as FIG. 1, the horizontal direction in the figure is called an X direction (corresponding to the first direction), the vertical direction in the figure is called a Y direction (corresponding to the second direction), and the direction perpendicular to the substrate plane is called a Z direction (corresponding to the depth direction). Also, “VDD” indicates a power supply voltage, a high-voltage side power supply itself, or a high-voltage side power supply line, and “VSS” indicates a power supply voltage, a low-voltage side power supply itself, or a low-voltage side power line. Note also that standard cells are herein simply referred to as “cells” as appropriate. As used herein, a “dummy gate interconnect” refers to a gate interconnect that does not constitute a transistor.

### First Embodiment

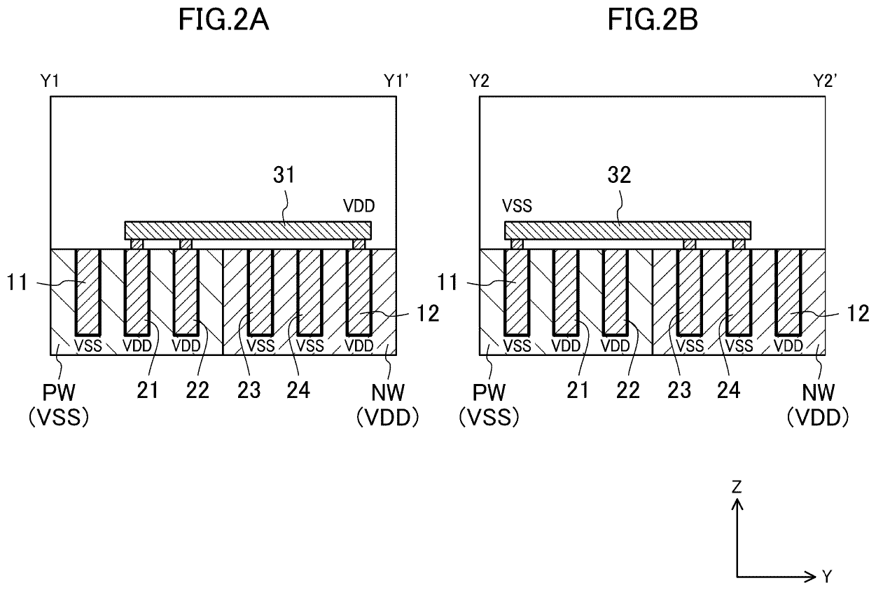

FIG. 1 is a plan view showing a layout example of a standard cell provided in a semiconductor integrated circuit device according to this embodiment, FIG. 2A is a cross-sectional view showing a cross-sectional structure taken along line Y1-Y1′ in FIG. 1, and FIG. 2B is a cross-sectional view showing a cross-sectional structure taken along line Y2-Y2′ in FIG. 1. The standard cell shown in FIGS. 1, 2A, and 2B is a capacitive cell.

The semiconductor integrated circuit device of this embodiment is formed on a chip substrate, and a plurality of cells including the standard cell shown in FIG. 1 are arranged in line in the X direction. A p-type region PW and an n-type region NW are formed in the substrate. The p-type region PW is a p-type substrate or a p-type well and corresponds to the first impurity region of the first conductivity type. The n-type region NW is an n-type substrate or an n-type well and corresponds to the second impurity region of the second conductivity type. The p-type region PW is supplied with VSS that corresponds to the first power supply voltage, and the n-type region NW is supplied with VDD that corresponds to the second power supply voltage.

As shown in FIG. 1, buried power rails 11 and 12 are placed near the lower end and near the upper end, respectively, of the standard cell in the figure. The buried power rail 11 is laid in the p-type region PW and supplies VSS. The buried power rail 12 is laid in the n-type region NW and supplies VDD. With the arrangement of a plurality of standard cells including the standard cell shown in FIG. 1 in line in the X direction, the buried power rails 11 and 12 form continuous buried power rails extending in the X direction.

In the p-type region PW, buried power rails 21 and 22 are provided in addition to the buried power rail 11. In the n-type region NW, buried power rails 23 and 24 are provided in addition to the buried power rail 12. The buried power rails 21, 22, 23, and 24 extend in the X direction. The buried power rails 21 and 22 are connected to the buried power rail 12, which supplies VDD, through a local interconnect (abbreviated as LI in the FIG. 31 extending in the Y direction and vias. That is, VDD is supplied to the buried power rails 21 and 22. The buried power rails 23 and 24 are connected to the buried power rail 11, which supplies VSS, through a local interconnect 32 extending in the Y direction and vias. That is, VSS is supplied to the buried power rails 23 and 24.

The buried power rails 21 and 22 supplied with VDD form capacitances with the p-type region PW supplied with VSS via insulating films. The buried power rails 23 and 24 supplied with VSS form capacitances with the n-type region NW supplied with VDD via insulating films.

Both ends of the buried power rails 21, 22, 23, and 24 in the X direction are apart from the cell boundaries in the X direction. Therefore, when a plurality of cells including the standard cell shown in FIG. 1 are arranged in line in the X direction, the buried power rails 21, 22, 23, and 24 are avoided from short-circuiting with buried power rails and transistors of adjacent cells.

Also, in the standard cell of FIG. 1, dummy gate interconnects 41, 42, 43, 44, and 45 extending in the Y direction are arranged at a constant pitch. It is however acceptable not to provide such dummy gate interconnects.

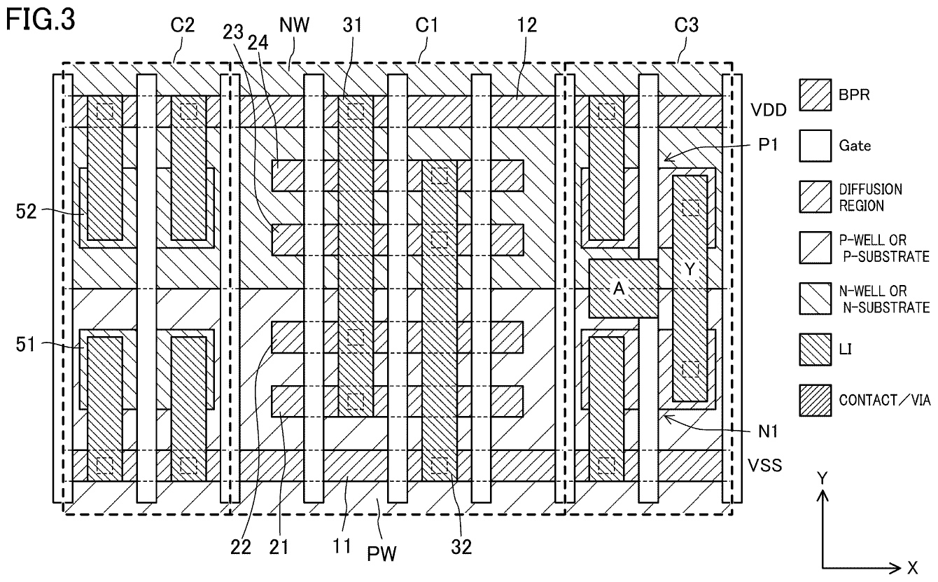

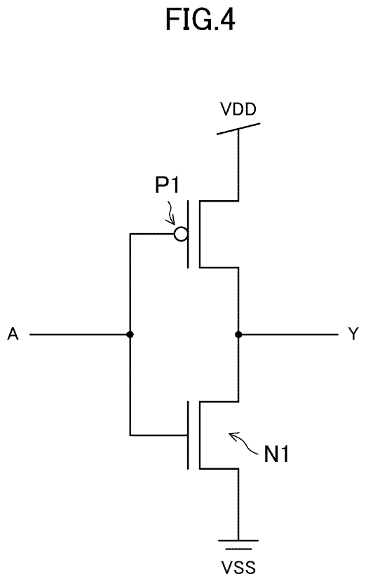

FIG. 3 shows an layout example of a plurality of cells including the standard cell of FIG. 1 arranged in line, where C1 is the capacitive cell shown in FIGS. 1, 2A, and 2B. A cell C2, which is a well tap cell, is adjacent to the cell C1 on the left in the figure. A cell C3, which is an inverter cell, is adjacent to the cell C1 on the right in the figure. FIG. 4 is a circuit diagram of an inverter implemented by the cell C3.

The cell C2 includes a p-type diffusion layer 51 formed on the p-type region PW and an n-type diffusion layer 52 formed on the n-type region NW. The potential of the diffusion layer 51 is fixed to VSS, and the potential of the diffusion layer 52 is fixed to VDD. The cell C3 includes an n-type transistor N1 formed in the p-type region PW and a p-type transistor P1 formed in the n-type region NW. The transistors may be of any form, including a nanosheet transistor, a fin transistor, and a planar transistor.

The potential of the p-type region PW is fixed to VSS by the cell C2, and in the cell C1, capacitances are formed between the buried power rails 21 and 22 supplied with VDD and the p-type region PW. Also, the potential of the n-type region NW is fixed to VDD by the cell C2, and in the cell C1, capacitances are formed between the buried power rails 23 and 24 supplied with VSS and the n-type region NW. The cell C2 also has the role of supplying VSS to the p-type region PW and VDD to the n-type region NW for other logic cells such as the sell C3.

As described above, according to this embodiment, in the plurality of standard cells C1, C2, and C3, the buried power rail 11 supplying VSS is laid in the p-type region PW supplied with VSS, and extends in the X direction. Also, the buried power rail 12 supplying VDD is laid in the n-type region NW supplied with VDD, and extends in the X direction. In the cell C1, the buried power rails 21 and 22 supplied with VDD are laid in the p-type region PW. This forms capacitances between the buried power rails 21 and 22 and the p-type region PW, whereby the cell C1 can obtain sufficient capacitance as the capacitive cell.

Also, in the cell C1, the buried power rails 23 and 24 supplied with VSS are laid in the n-type region NW. This forms capacitances between the buried power rails 23 and 24 and the n-type region NW, whereby the cell C1 can obtain further sufficient capacitance as the capacitive cell.

Moreover, by increasing the size in the depth direction of the capacitance-forming buried power rails 21, 22, 23, and 24, the capacitance value can be increased.

Also, by placing the cell C2, which is a well tap cell, adjacent to the cell C1, which is a capacitive cell, as shown in FIG. 3, the resistance values between the cells C1 and C2 in the p-type region PW and the n-type region NW can be reduced. This allows the capacitance of the cell C1 to function more effectively. Note however that the well tap cell may be placed apart from the capacitive cell.

Such well tap cells may be placed on both sides of the capacitive cell. Otherwise, the capacitive cell and the well tap cell may be configured as a single cell.

### Alteration 1

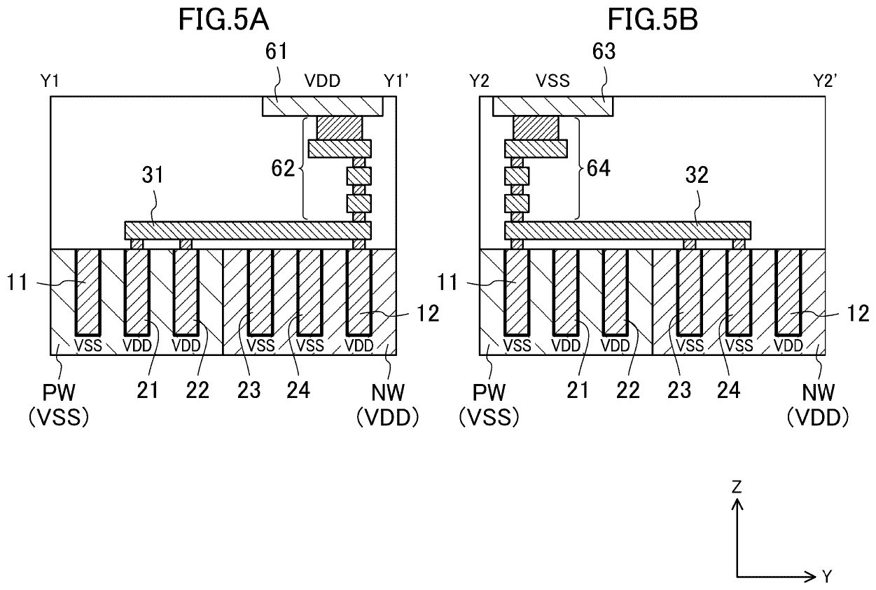

FIGS. 5A and 5B are views showing cross-sectional structures of a standard cell of Alteration 1. Note that the planar structure is similar to that of FIG. 1 in the above-described embodiment.

As shown in FIG. 5A, an external pad 61 for connection with the outside of the chip is provided on the surface of the substrate. VDD is supplied to the external pad 61 from outside the chip. The local interconnect 31 is connected to the external pad 61 through an interconnect structure 62 constituted by interconnects formed in a plurality of interconnect layers and vias. With this configuration, VDD is supplied to the buried power rails 21 and 22 from the external pad 61.

As shown in FIG. 5B, an external pad 63 for connection with the outside of the chip is provided on the surface of the substrate. VSS is supplied to the external pad 63 from outside the chip. The local interconnect 32 is connected to the external pad 63 through an interconnect structure 64 constituted by interconnects formed in a plurality of interconnect layers and vias. With this configuration, VSS is supplied to the buried power rails 23 and 24 from the external pad 63.

Note that, while the interconnect structure 62 is provided right above the local interconnect 31 and has three interconnect layers in FIG. 5A, the placement and configuration of the interconnect structure connecting the external pad 61 and the local interconnect 31 are not limited to this. Similarly, while the interconnect structure 64 is provided right above the local interconnect 32 and has three interconnect layers, the placement and configuration of the interconnect structure connecting the external pad 63 and the local interconnect 32 are not limited to this.

### Alteration 2

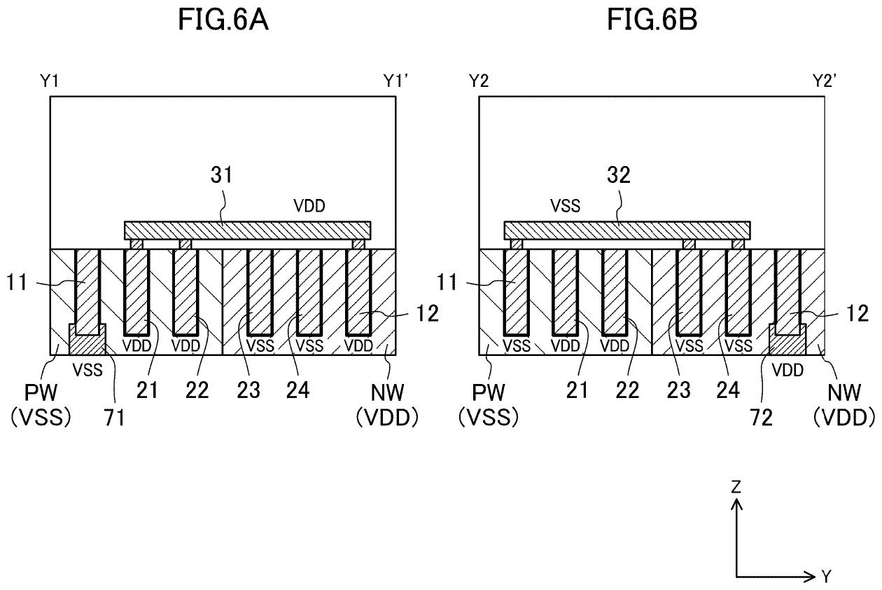

FIGS. 6A and 6B are views showing cross-sectional structures of a standard cell of Alteration 2. Note that the planar structure is similar to that of FIG. 1 in the above-described embodiment.

As shown in FIG. 6A, the buried power rail 11 supplying VSS is connected to an external pad (not shown) for connection with the outside of the chip formed on the back of the substrate through a through silicon via (TSV) 71. Note that no insulating film is formed on the portion of the buried power rail 11 connected to the TSV 71. VSS is supplied to the external pad from outside the chip. With this configuration, the buried power rail 11 is supplied with VSS from outside on the back side of the chip.

As shown in FIG. 6B, the buried power rail 12 supplying VDD is connected to an external pad (not shown) for connection with the outside of the chip formed on the back of the substrate through a TSV 72. Note that no insulating film is formed on the portion of the buried power rail 12 connected to the TSV 72. VDD is supplied to the external pad from outside the chip. With this configuration, the buried power rail 12 is supplied with VDD from outside on the back side of the chip.

Note that, while the TSV 71 is provided for the buried power rail 11 in FIG. 6A, the configuration is not limited to this. For example, a TSV may be provided for a power supply line supplying VSS formed in an upper interconnect layer and connected to an external pad. Similarly, while the TSV 72 is provided for the buried power rail 12 in FIG. 6B, the configuration is not limited to this. For example, a TSV may be provided for a power supply line supplying VDD formed in an upper interconnect layer and connected to an external pad. In this case, the TSV may be provided outside the standard cell.

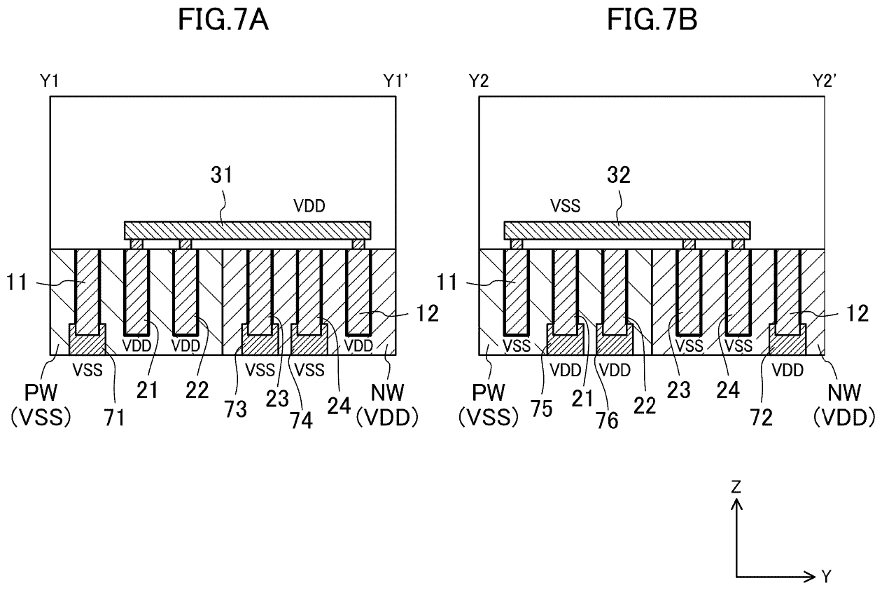

Also, as shown in FIGS. 7A and 7B, a TSV may be provided for a capacitance-forming buried power rail and connected to an external pad. In FIG. 7A, TSVs 73 and 74 are provided for the buried power rails 23 and 24, respectively, and connected to an external pad (not shown) to which VSS is supplied. No insulating film is formed on the portions of the buried power rails 23 and 24 connected to the TSVs 73 and 74. In FIG. 7B, TSVs 75 and 76 are provided for the buried power rails 21 and 22, respectively, and connected to an external pad (not shown) to which VDD is supplied. No insulating film is formed on the portions of the buried power rails 21 and 22 connected to the TSVs 75 and 76.

With the above configuration, since VDD is directly supplied to the capacitance-forming buried power rails 21 and 22 and VSS is directly supplied to the capacitance-forming buried power rails 23 and 24, the resistance values from the power supplies to the buried power rails are reduced. This allows the capacitance of the capacitive cell to function more effectively.

### Second Embodiment

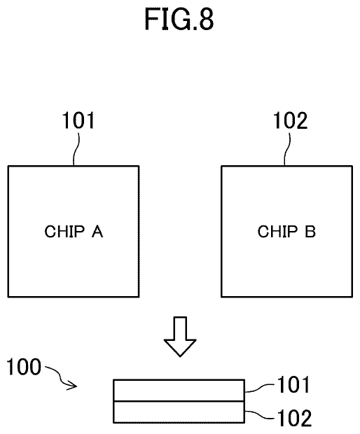

FIG. 8 is a view showing an overall configuration of a semiconductor integrated circuit device according to the second embodiment. As shown in FIG. 8, the semiconductor integrated circuit device 100 is constituted by a first semiconductor chip 101 (chip A, main chip) and a second semiconductor chip 102 (chip B, back chip) stacked one upon the other. In the first semiconductor chip 101, a circuit including a plurality of transistors is formed. The second semiconductor chip 102 includes no elements such as transistors, but has power supply lines formed in a plurality of interconnect layers. In the stack, the back surface of the first semiconductor chip 101 and the principal surface of the second semiconductor chip 102 face each other.

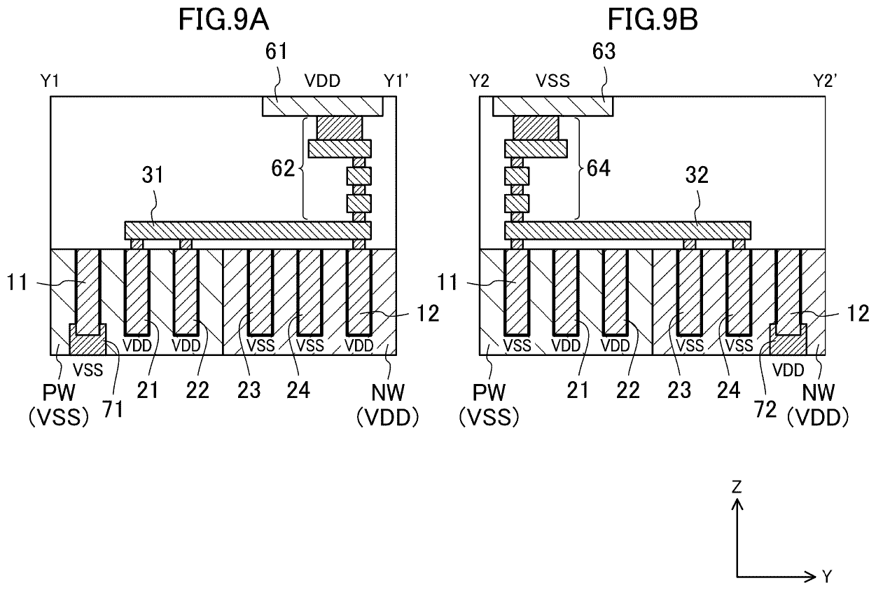

FIGS. 9A and 9B are views showing cross-sectional structures of a standard cell included in the first semiconductor chip 101 in this embodiment. Note that the planar structure is similar to that of FIG. 1 in the first embodiment described above.

As shown in FIG. 9A, the external pad 61 is provided on the principal surface of the first semiconductor chip 101. VDD is supplied to the external pad 61 from outside the semiconductor integrated circuit device. The local interconnect 31 is connected to the external pad 61 through the interconnect structure 62 constituted by interconnects formed in a plurality of interconnect layers and vias. Also, the buried power rail 11 supplying VSS is connected to an external pad (not shown) formed on the back of the first semiconductor chip 101 through the TSV 71. This external pad is connected to the second semiconductor chip 102, i.e., connected to a VSS power supply line formed in the second semiconductor chip 102.

As shown in FIG. 9B, the external pad 63 is provided on the principal surface of the first semiconductor chip 101. VSS is supplied to the external pad 63 from outside the semiconductor integrated circuit device. The local interconnect 32 is connected to the external pad 63 through the interconnect structure 64 constituted by interconnects formed in a plurality of interconnect layers and vias. Also, the buried power rail 12 supplying VDD is connected to an external pad (not shown) formed on the back of the first semiconductor chip 101 through the TSV 72. This external pad is connected to the second semiconductor chip 102, i.e., connected to a VDD power supply line formed in the second semiconductor chip 102.

According to this embodiment, as in the first embodiment, a capacitive cell capable of obtaining sufficient capacitance can be implemented in the semiconductor integrated circuit device having buried power rails.

Note that, in this embodiment, as in the configuration shown in FIGS. 7A and 7B, TSVs may be provided for the capacitance-forming buried power rails and connected to external pads, which may be then connected to a power supply line formed in the second semiconductor chip 102.

Alternatively, the second semiconductor chip 102 may be used as a chip having a circuit including a plurality of transistors, and the first semiconductor chip 101 as a chip having no elements such as transistors but having power supply lines formed in a plurality of interconnect layers. In this configuration, the standard cell shown in FIGS. 9A and 9B is to be provided in the second semiconductor chip 102, and the external pads 61 and 63 are to be provided on the back side of the second semiconductor chip 102.

According to the present disclosure, the semiconductor integrated circuit device having buried power rails can obtain sufficient capacitance. The present disclosure is therefore useful for improving the performance of system LSI, for example.

1. A semiconductor integrated circuit device, comprising:
a plurality of standard cells including a first standard cell, arranged in line in a first direction,
wherein
the plurality of standard cells include
a first impurity region of a first conductivity type formed in a substrate and supplied with a first power supply voltage,
a second impurity region of a second conductivity type formed in the substrate and supplied with a second power supply voltage,
a first buried power rail laid in the first impurity region, extending in the first direction and supplying the first power supply voltage, and
a second buried power rail laid in the second impurity region, extending in the first direction and supplying the second power supply voltage, and
the first standard cell includes
a third buried power rail laid in the first impurity region and supplied with the second power supply voltage.

2. The semiconductor integrated circuit device of claim 1, wherein
the first standard cell includes
a fourth buried power rail laid in the second impurity region and supplied with the first power supply voltage.

3. The semiconductor integrated circuit device of claim 1, wherein
the third buried power rail extends in the first direction, and both ends in the first direction of the third buried power rail are apart from cell boundaries of the first standard cell in the first direction.

4. The semiconductor integrated circuit device of claim 1, wherein
the plurality of standard cells include a second standard cell adjacent to the first standard cell in the first direction, and
the second standard cell is a well tap cell supplying the first power supply voltage to the first impurity region and supplying the second power supply voltage to the second impurity region.

5. The semiconductor integrated circuit device of claim 1, wherein
the first standard cell includes
a first local interconnect extending in a second direction perpendicular to the first direction and connecting the second buried power rail and the third buried power rail.

6. The semiconductor integrated circuit device of claim 5, comprising:
an external pad provided on a principal surface of the substrate and used for external connection, and
an interconnect structure having a plurality of interconnects formed in a plurality of interconnect layers, and connecting the first local interconnect and the external pad.

7. The semiconductor integrated circuit device of claim 1, wherein
the first standard cell includes
a first contact provided between the first buried power rail and a back of the substrate.

8. The semiconductor integrated circuit device of claim 7, wherein
the first standard cell includes
a second contact provided between the third buried power rail and the back of the substrate.
